(19) United States
(12) Patent Application Publication
(10) Pub. No.: US 2026/0032957 A1
(43) Pub. Date: Jan. 29, 2026

(54) SEMICONDUCTOR STRUCTURE WITH REDUCED PARASITIC CAPACITANCE AND METHOD FOR MANUFACTURING THE SAME

(71) Applicant: TAIWAN SEMICONDUCTOR MANUFACTURING COMPANY, LTD., Hsinchu (TW)

(72) Inventor: Chia-Yun CHENG, Hsinchu (TW)

(73) Assignee: TAIWAN SEMICONDUCTOR MANUFACTURING COMPANY, LTD., Hsinchu (TW)

(21) Appl. No.: 18/781,706

(22) Filed: Jul. 23, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/015; H10D 64/017; H10D 64/018; H10D 84/013; H10D 84/038; H10D 84/83

(57) ABSTRACT

A method for forming an air gap structure in a semiconductor structure includes: forming a stacking portion on a substrate, the stacking portion including a first semiconductor layer and a second semiconductor layer disposed on the first semiconductor layer; recessing the first semiconductor layer to form two grooves which are respectively located beneath two end portions of the second semiconductor layer; forming two inner spacers to fill the two grooves, respectively; and performing a treatment such that the air gap structure is formed in each of the two inner spacers.

### BACKGROUND

Nowadays, integrated circuits (ICs) are widely used in consumer electronics products and automotive electronics products. With the advancement of IC manufacturing technologies, electronics products are designed to have relatively small and complex circuits. Transistors are key active components in modern ICs. In order for the electronics products to have relatively low power consumption, long service lifetime, high computing speed, and so on, various approaches are being continuously developed for optimizing the transistors in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 14F illustrate schematic views of intermediate stages of the method depicted in FIG. 1 in accordance with some embodiments.

FIG. 15 is a graph illustrating thermogravimetric analysis (TGA) results of Samples A, B and C, in which Sample A, B and C are different silicon-containing polymers used in the method in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects #10%, in some aspects+5%, in some aspects+2.5%, in some aspects+1%, in some aspects+0.5%, and in some aspects+0.1% from the specified amount, as such variations are appropriate to perform the disclosed methods or employ the disclosed compositions.

The term “source/drain portion(s)” may refer to a source or a drain, individually or collectively dependent upon the context.

With the size miniaturization of a semiconductor device, parasitic capacitance in the semiconductor device increases, which may have adverse effect on the electrical performance of the semiconductor device. Gate-all-around (GAA) structure is one of three-dimensional transistor structures in advanced technology nodes of semiconductor fabrication. In the GAA structure, a control gate wraps around each channel so that the current flowing in each channel can be well controlled by the control gate, thereby reducing short channel effects in the semiconductor device. The parasitic capacitance in the GAA structure includes a parasitic capacitance between the control gate and the channel(s), another parasitic capacitance between the control gate and a source (or a drain), and still another parasitic capacitance between the control gate and a metal contact disposed on the source (or the drain). Among the various parasitic capacitances as mentioned above, the parasitic capacitance between the control gate and the source (or the drain) may be reduced by reducing a dielectric constant of an inner spacer, which is disposed to separate the control gate from the source (or the drain). In common practice, the inner spacer is formed by chemical vapor deposition (CVD) or atomic layer deposition (ALD), followed by an etching process to remove an excess portion of a dielectric material for forming the inner spacer. The dielectric constant of the dielectric material may be reduced by adjusting atomic percentage of elements (e.g., silicon, carbon, oxygen, and/or nitrogen) in the dielectric material. For example, the dielectric constant of the dielectric material may be reduced by adjusting process parameters (e.g., flow rate, etc.) of precursor gases including the abovementioned elements, but the effect brought about by reducing the dielectric constant of the dielectric material is limited.

Therefore, the present disclosure is directed to a semiconductor structure including inner spacers each of which is formed with an air gap therein, and a method for manufacturing the semiconductor structure. With the provision of the inner spacers each having the air gap, the parasitic capacitance between the control gate and the source (or the drain) may be effectively reduced.

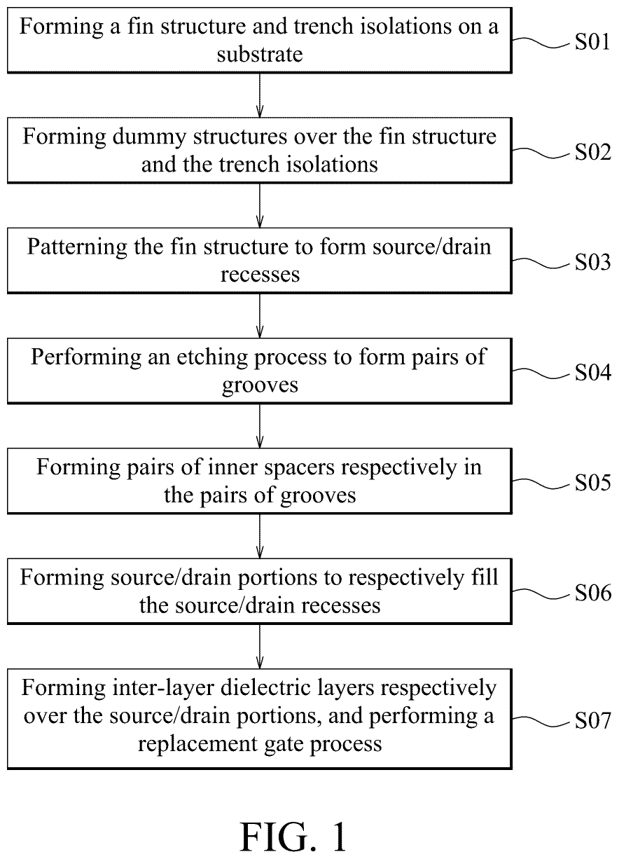

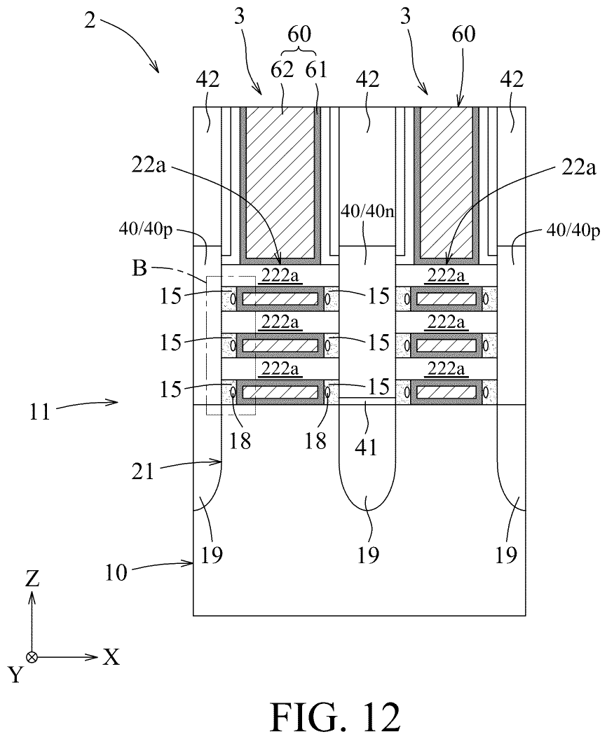

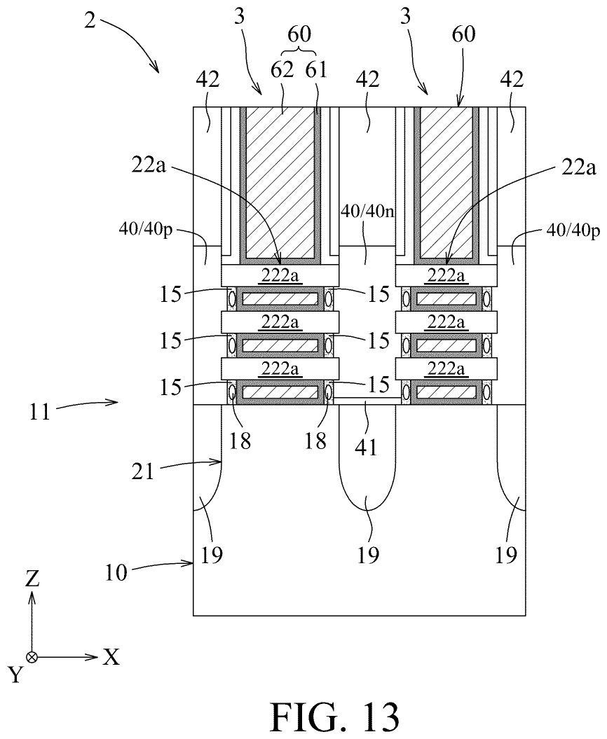

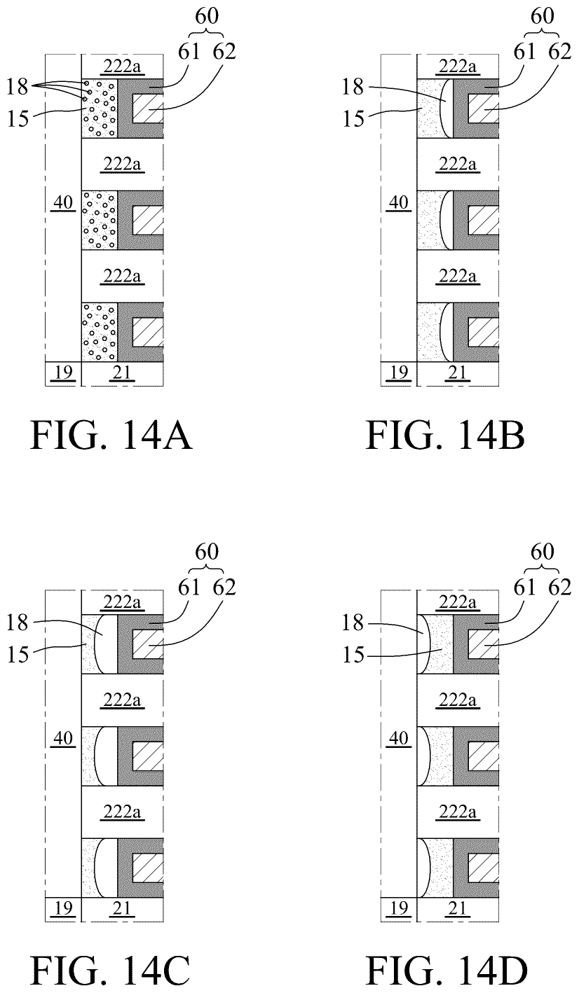

FIG. 1 is a flow diagram illustrating a method 1 for forming an air gap structure in a semiconductor structure (for example, but not limited to, a semiconductor structure 2 shown in FIG. 12 or 13) in accordance with some embodiments. The semiconductor structure 2 shown in FIG. 12 or 13 is configured as a GAA structure including two gate-all-around field-effect transistors (GAAFETs) 3 disposed on the same fin, but is not limited thereto. In some embodiments not shown herein, the semiconductor structure may be configured as a complementary field-effect transistor (CFET) structure which includes a lower GAAFET and an upper GAAFET sequentially formed over a substrate, a fork-sheet structure which includes two GAAFETs which are formed on different fins and which are spaced part from each other through a wall portion that is formed on an trench isolation, or other suitable three-dimensional structures. The semiconductor structure 2 may function as memory devices, logic devices, power devices, or other suitable devices.

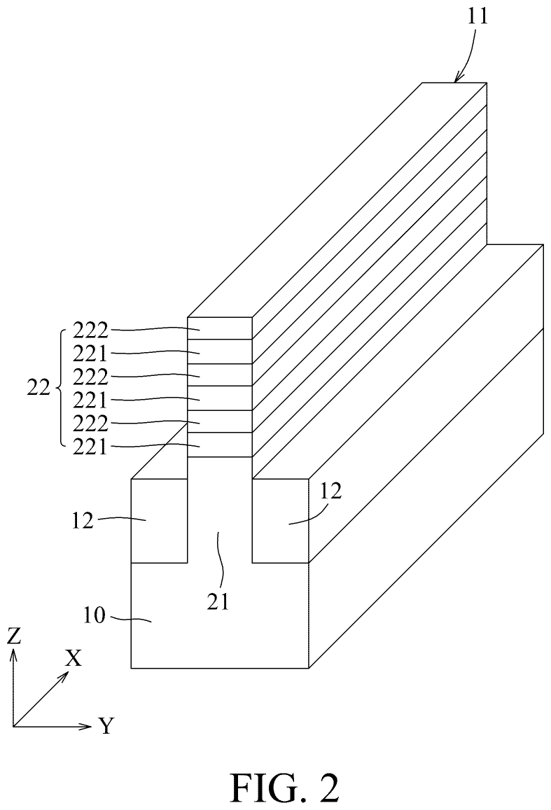

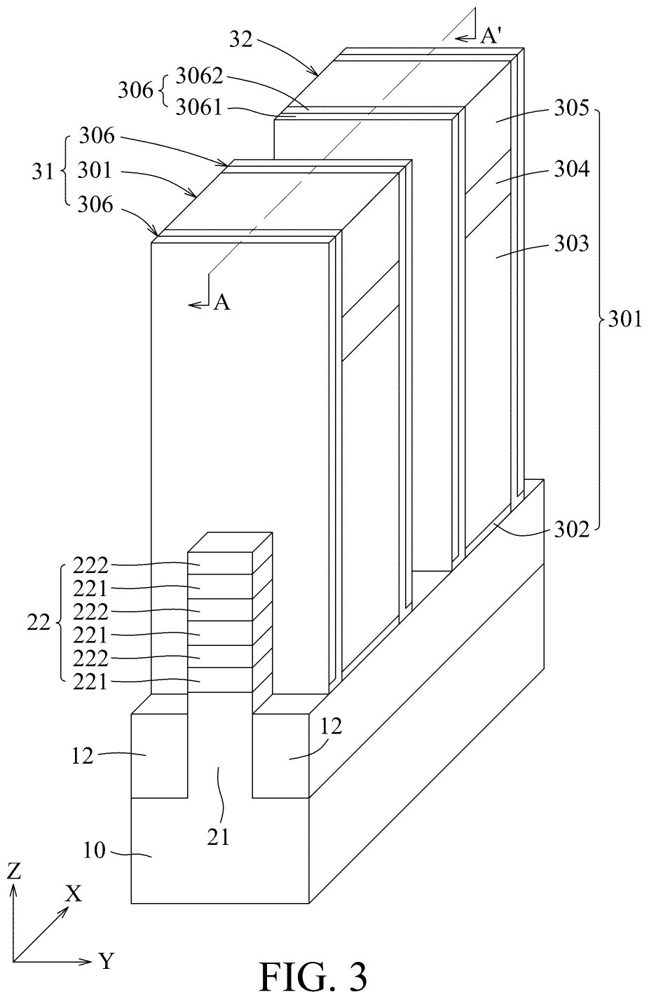

The method 1 may include steps S01 to S07. FIGS. 2 to 14F illustrate schematic views of intermediate stages of the method 1 in accordance with some embodiments.

Referring to FIG. 1 and the example illustrated in FIG. 2, the method 1 begins at step S01, where a fin structure 11 is formed on a substrate 10, and then two trench isolations 12 are formed on the substrate 10. The two trench isolations 12 are respectively located at two opposite sides of the fin structure 11 in a Y direction.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the substrate 10 may be formed with an n-type well having an n-type conductivity and a p-type well having a p-type conductivity. Each of the n-type well and the p-type well may be formed by introducing an n-type impurity or a p-type impurity into the substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 10 may be configured as a semiconductor-on-insulator substrate. Other suitable materials and configurations for the substrate 10 are within the contemplated scope of the present disclosure.

The fin structure 11 is elongated in an X direction transverse to the Y direction, and includes a fin 21 and a stack 22 which is disposed on the fin 21. In some embodiments, the fin 21 may be implanted with a p-type impurity to serve as a p-type well, or may be implanted with an n-type impurity to serve as an n-type well. The examples of the p-type impurity and the n-type impurity are similar to those as described in the previous paragraph.

The stack 22 includes first layers 221 and second layers 222 disposed to alternate with the first layers 221 in a Z direction transverse the X and Y directions. In some embodiments, the X, Y and Z directions are perpendicular to each other. In some embodiments, an uppermost one of the second layers 222 is disposed over an uppermost one of the first layers 221 opposite to the substrate 10. In some embodiments, a lowermost one of the second layers 222 is spaced apart from the fin 21 by a lowermost one of the first layers 221. Each of the first layers 221 is made of a first semiconductor material, and each of the second layers 222 is made of a second semiconductor material that is different from the first semiconductor material, so that the first layers 221 may be selectively removed with the second layers 222 being substantially intact due to different etching selectivity ratios. Possible semiconductor materials suitable for forming the first and second layers 221, 222 are similar to those for forming the substrate 10, and thus the details thereof are omitted for the sake of brevity. In some embodiments, the first layers 221 are made of silicon germanium, and the second layers 222 are made of silicon. Other materials suitable for the first layers 221 and the second layers 222 are within the contemplated scope of the present disclosure.

In some embodiments, formation of the fin structure 11 may include (i) forming a lamination structure (not shown) on a starting substrate (not shown) by CVD, ALD, an epitaxial growth process (such as molecular-beam epitaxy (MBE), selective area epitaxy (SAE), etc.), or other suitable deposition techniques, and (ii) patterning the lamination structure and the starting substrate using a photolithography process followed by an etching process. As a result, the lamination structure is patterned into the stack 22 of the fin structure 11 each having a predetermined dimension in the Y direction, and the starting substrate is patterned into the substrate 10 and the fin 21 of the fin structure 11.

In some embodiments, the trench isolations 12 may each be a shallow trench isolation (STI), a deep trench isolation (DTI), or other suitable structures. In some embodiments, the trench isolations 12 may include silicon oxide, silicon nitride, silicon oxynitride, other low-k dielectric materials, or combinations thereof. Other insulating materials suitable for the trench isolations 12 are within the contemplated scope of the present disclosure.

In some embodiments, formation of the trench isolations 12 may include (i) forming an isolation layer over the substrate 10 and the fin structure 11 followed by a planarization process (for example, but not limited to, chemical mechanism polishing (CMP)) to form two isolation regions (not shown) respectively located at the two opposite sides of the fin structure 11 in the Y direction, and (ii) recessing the two isolation regions such that the two isolation regions are respectively formed into the two trench isolations 12.

Referring to FIG. 1 and the example illustrated in FIG. 3, the method 1 proceeds to step S02, where dummy structures 31, 32 are formed. FIG. 3 is a schematic perspective view similar to that of FIG. 2, but illustrating the structure after step S02.

The dummy structures 31, 32 are spaced apart from each other in the X direction. Each of the dummy structures 31, 32 is elongated in the Y direction and is formed over the fin structure 11 and the trench isolations 12, so that the fin structure 11 has exposed portions which are exposed from the dummy structures 31, 32 and which are disposed to alternate with the dummy structures 31, 32.

Each of the dummy structures 31, 32, 33 includes a main portion 301, and two spacers 306 respectively disposed at two opposite sides of the main portion 301 in the X direction.

The main portion 301 includes a dummy dielectric 302, a dummy gate 303, a polish stop layer 304, and a hard mask 305. The dummy dielectric 302 is disposed over the fin structure 11 and the trench isolations 14. The dummy gate 303, the polish stop layer 304 and the hard mask 304 are sequentially formed on the dummy dielectric 302. In some embodiments, the dummy dielectric 302 may include silicon oxide, silicon nitride, silicon oxynitride, high dielectric constant (k) materials, other suitable dielectric materials, or combinations thereof. In some embodiments, the dummy gate 303 may include polycrystalline silicon, single crystalline silicon, amorphous silicon, or combinations thereof. The polish stop layer 304 and the hard mask 305 are made of different materials. In some embodiments, possible materials suitable for the polish stop layer 304 and the hard mask 305 may include silicon nitride, silicon oxide, silicon oxynitride, or combinations thereof. Other materials suitable for the main portion 301 are within the contemplated scope of the present disclosure. In some embodiments, formation of the main portion 301 may include (i) sequentially forming a first dummy layer (not shown) for forming the dummy dielectric 302 and a second dummy layer (not shown) for forming the dummy gate 303 over the fin structure 11 and the trench isolations 12 by CVD, ALD, physical vapor deposition (PVD), or other suitable deposition techniques, (ii) performing a planarization process (e.g., chemical mechanical polishing) to obtain a planar upper surface of the second dummy layer, (iii) sequentially forming a third dummy layer (not shown) for forming the polish stop layer 304 and a fourth dummy layer (not shown) for forming the hard mask 305 on the planarized second dummy layer, and (iv) patterning the first dummy layer, the planarized second dummy layer, the third dummy layer, and the fourth dummy layer using a photolithography process followed by an etching process, thereby obtaining the main portion 301. It is noted that the main portion 301 of the dummy structure 31 may have a width in the X direction that is the same as or different from a width of the main portion 301 of the dummy structure 32 in the X direction. For example, as shown in FIG. 3, the width of the width of the main portion 301 of the dummy structure 31 is greater than the width of the width of the main portion 301 of the dummy structure 32.

In some embodiments, each of the spacers 306 may be formed as a single layer structure or a multi-layered structure. In some embodiments, as shown in FIG. 3, each of the spacers 306 is formed as a bi-layer structure, and includes an outer sub-layer 3061 and an inner sub-layer 3062 which is disposed between the outer sub-layer 3061 and a main portion 301. The outer and inner sub-layers 3061, 3062 are made of different materials. In some embodiments, possible materials suitable for the spacers 306 may include, for example, but not limited to, a silicon oxide (e.g., SiO₂) based dielectric material, a silicon nitride (e.g., Si₃N₄) based dielectric material, a carbon-doped silicon oxide material, a nitride-doped silicon oxide material, a porous oxide material, other suitable low dielectric constant (k) materials, or combinations thereof. In some embodiments, formation of the spacers 306 includes conformally depositing material(s) of the spacers 306 to cover the main portion 301 and the exposed portions of the fin structure 11 and the isolation trenches 12 by CVD, ALD, PVD, or other suitable deposition techniques, and performing an anisotropic etching process on the material(s) of the spacers 306 to expose upper surfaces of the main portion 301 and the exposed portions of the fin structure 11 and the isolation trenches 12 such that portions of the material(s) of the spacers 306 remain at side surfaces of the main portion 301, thereby obtaining the spacers 306. In some embodiments, during formation of the spacers 306, the material(s) of the spacers 306 is also formed into multi-pairs of fin sidewalls (not shown). Each pair of the fin sidewalls are formed at two opposite sides of a respective one of the exposed portions of the fin structure 11 in the Y direction.

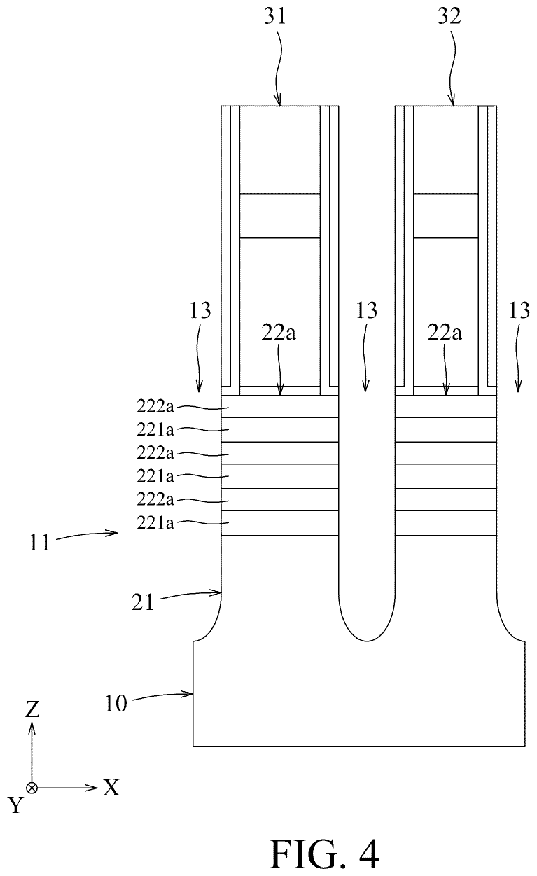

Referring to FIG. 1 and the examples illustrated in FIG. 4, the method 1 proceeds to step S03, where the exposed portions of the fin structure 11 (see FIG. 3) are patterned to form source/drain recesses 13, respectively, by an etching technique (for example, but not limited to, dry etching, wet etching, or a combination thereof). FIG. 4 is a schematic sectional view taken along line A-A′ of FIG. 3, but illustrating the structure after step S03.

In step S03, the stack 22 in the fin structure 11 (see FIG. 3) is patterned into stacking portions 22a which are respectively located beneath the dummy structures 31, 32, and thus portions of the fin 21 are respectively exposed from the source/drain recesses 13. In some embodiments, the exposed portions of the fin 21 are further etched to deepen the source/drain recesses 13. The stacking portions 22a are disposed to alternate with the source/drain recesses 13 in the X direction. Each of the stacking portions 22a includes first films 221a which are respectively formed from the first layers 221, and second films 222a which are respectively formed from the second layers 222. The first films 221a and the second films 222a may be also referred to as first semiconductor layers and second semiconductor layers, respectively.

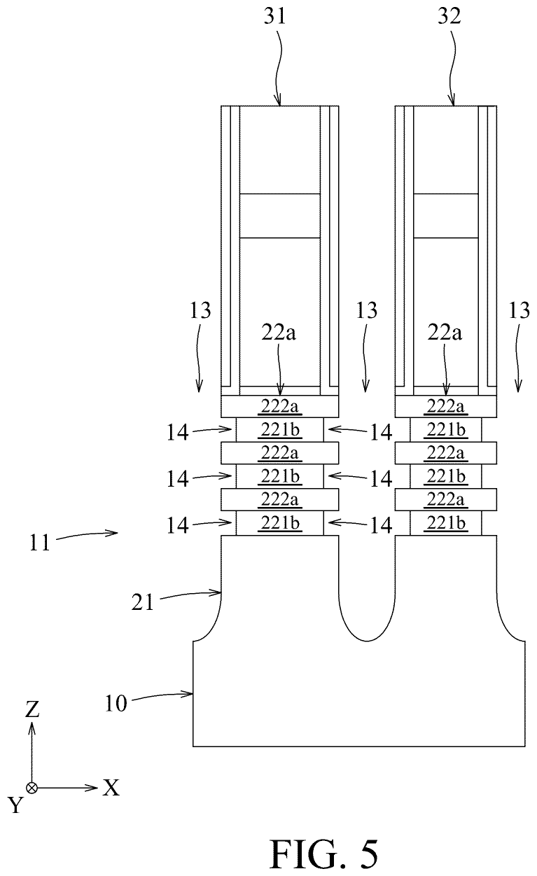

Referring to FIG. 1 and the examples illustrated in FIGS. 5, the method 1 proceeds to step S04, where an etching process is performed to form pairs of grooves 14. FIG. 5 is a schematic sectional view similar to that of FIG. 4, but illustrating the structure after step S04.

Each of the first films 221a in each stacking portion 22a has two side surfaces which are respectively exposed from two corresponding adjacent one of the source/drain recesses 13, as shown in FIG. 4. During the etching process, the first films 221a (see FIG. 4) are recessed such that each pair of the grooves 14 are respectively indented from the two side surfaces of a respective one of the first films 221a. As such, each pair of the grooves 14 are respectively located beneath two end portions of a respective one of the second films 222a.

It is noted that since the etching process used to recess the first films 221a has a high etching selectivity, the second films 222a are substantially intact after step S04. After step S04, the recessed first films are denoted by 221b.

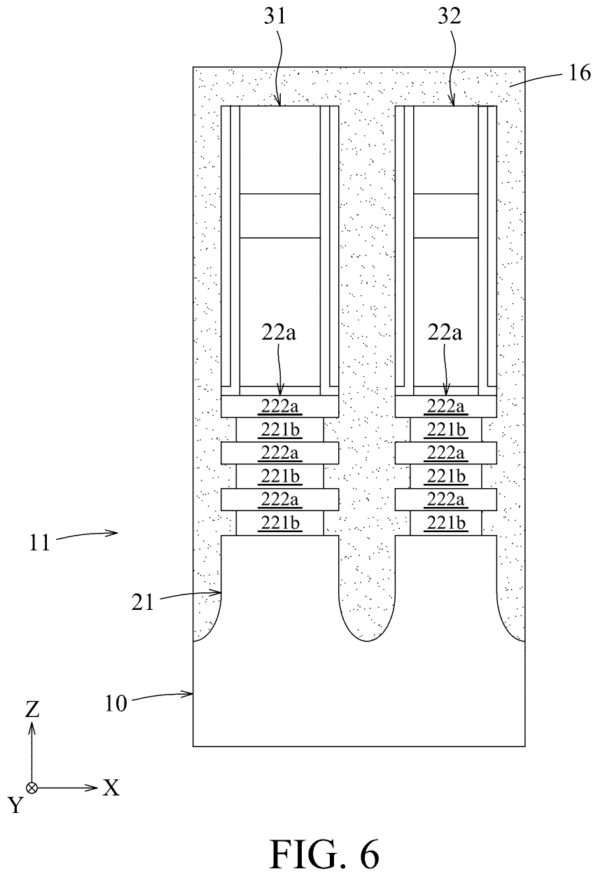

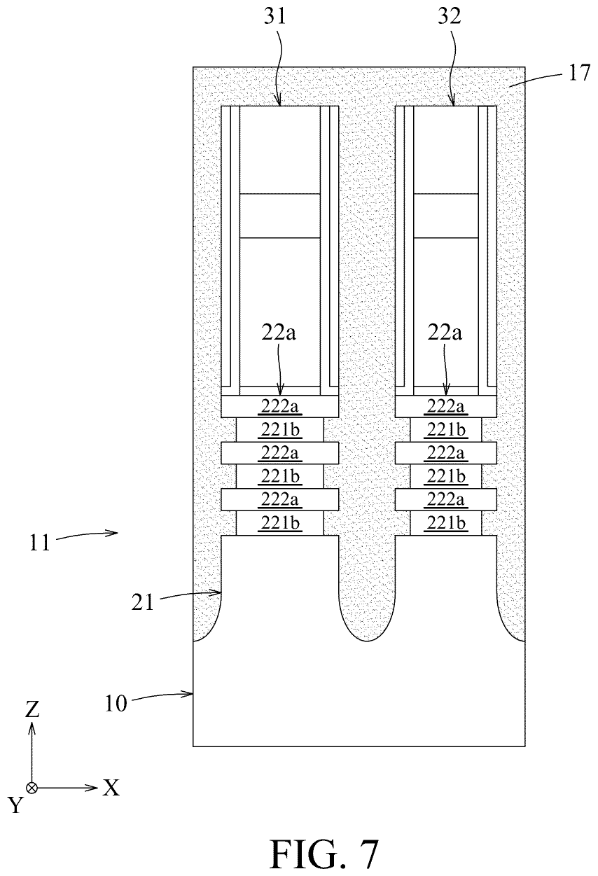

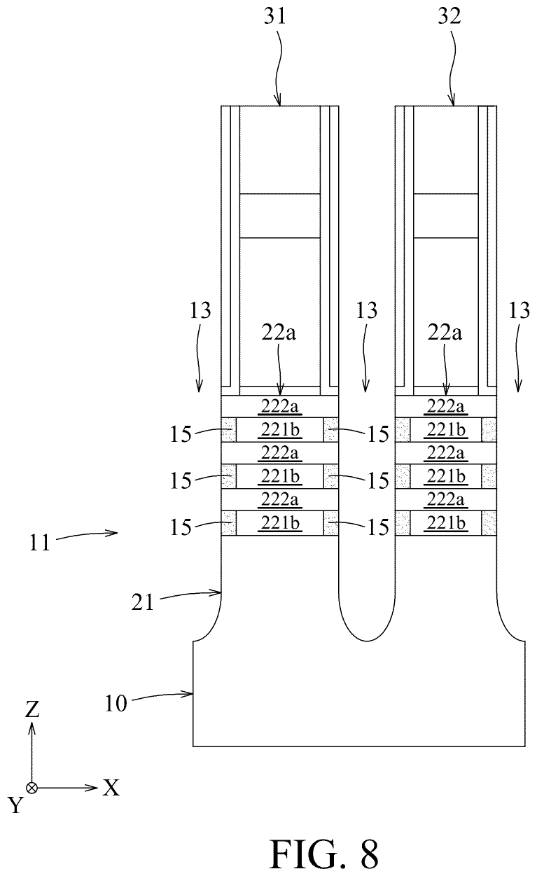

Referring to FIG. 1 and the examples illustrated in FIG. 8, the method 1 proceeds to step S05, where pairs of inner spacers 15 are respectively formed in the pairs of grooves 14. FIG. 8 is a schematic sectional view similar to that of FIG. 5, but illustrating the structure after step S05. FIGS. 6 and 7 illustrate two possible intermediate states in step S05 in accordance with some embodiments.

In some embodiments, step S05 may include multiple sub-steps as described in the following.

Firstly, a cleaning process is performed to remove native oxide, particles, and residues from inner surfaces of the pairs of grooves 14 and the source/drain recesses 13. In some embodiments, the cleaning process includes the use of a diluted hydrofluoric acid (DHF) solution. In some embodiments, the DHF solution is a mixture of hydrogen fluoride and water, and has a concentration of hydrogen fluoride ranging from about 0.1% (volume per volume) to about 10% (volume per volume). In some embodiments, the cleaning process is performed for a time period ranging about 30 seconds to about 60 seconds.

Afterwards, as shown in FIG. 6, a mixture 16 is applied over the dummy structures 31, 32 to fill the pairs of grooves 14 and the source/drain recesses 13. In some embodiments, the mixture 16 is applied by a spin-on coating process, or other suitable processes. In some embodiments, the spin-on coating process is performed at room temperature. The mixture 16 includes a solvent and a silicon-containing polymer dissolved in the solvent.

The silicon-containing polymer includes main repeating units, first repeating units and second repeating units. Each of the main repeating units is represented by formula (A):

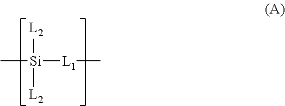

wherein
L₁ is oxygen or nitrogen,
L₂ is a hydroxyl group (OH) when L₁ is oxygen, and
L₂ is hydrogen when L₁ is nitrogen.

Each of the first repeating units is represented by formula (B):

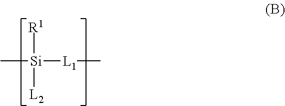

wherein
L₁ is oxygen or nitrogen,
L₂ is a hydroxyl group (OH) when L₁ is oxygen,
L₂ is hydrogen when L₁ is nitrogen, and
R¹ is a substituted or non-substituted C4 to C10 aromatic group, or a substituted or non-substituted C3 to C10 cycloalkyl group.

Hereinafter, R¹ is also referred to as a first functional unit. In some embodiments, the first functional unit is a nitrogen-substituted C4 to C10 aromatic group, or a nitrogen-substituted C3 to C10 cycloalkyl group. In some embodiments, the first functional unit is a non-substituted or nitrogen-substituted phenyl group. In some embodiments, the first functional unit is a non-substituted or nitrogen-substituted cyclohexyl group.

Each of the second repeating units is represented by formula (C):

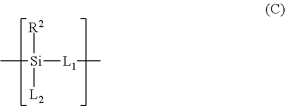

wherein
L₁ is oxygen or nitrogen,
L₂ is a hydroxyl group (OH) when L₁ is oxygen,
L₂ is hydrogen when L₁ is nitrogen, and
R² is a substituted or non-substituted C1 to C5 alkyl group.

Hereinafter, R² is also referred to as a second functional unit. In some embodiments, the second functional unit is a nitrogen-substituted C1 to C5 alkyl group. In some embodiments, the second functional unit is a non-substituted or nitrogen-substituted C1 to C2 alkyl group. In some embodiments, the second functional unit is a non-substituted or nitrogen-substituted C3 to C5 linear alkyl group. In some embodiments, the second functional unit is a non-substituted or nitrogen-substituted C3 to C5 branched alkyl group.

In some embodiments, the second repeating units are coupled to the main repeating unis through the first repeating units. In some embodiments, the silicon-containing polymer is represented by formula (I):

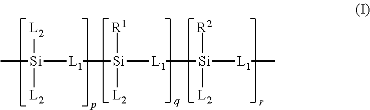

wherein
L₁ is oxygen or nitrogen,
L₂ is a hydroxyl group (OH) when L₁ is oxygen,
L₂ is hydrogen when L₁ is nitrogen,
R¹ is the first functional unit as described above,
R² is the second functional unit as described above,
each of p and q is an integer greater than zero, and
r is an integer not less than zero.

In some embodiments, when L₁ is oxygen and L₂ is a hydroxyl group (OH), the silicon-containing polymer has a backbone which includes silicon and oxygen. In such case, the silicon containing polymer is represented by formula (I-1):

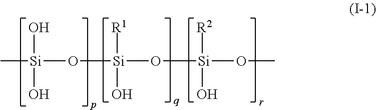

wherein
R¹ is the first functional unit as described above,
R² is the second functional unit as described above,
each of p and q is an integer greater than zero, and
r is an integer not less than zero.

In some embodiments, when L₁ is nitrogen and L₂ is a hydrogen, the silicon-containing polymer has a backbone which includes silicon and nitrogen. In such case, the silicon containing polymer is represented by formula (I-2):

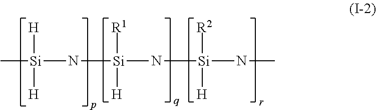

wherein
R¹ is the first functional unit as described above,
R² is the second functional unit as described above,
each of p and q is an integer greater than zero, and
r is an integer not less than zero.

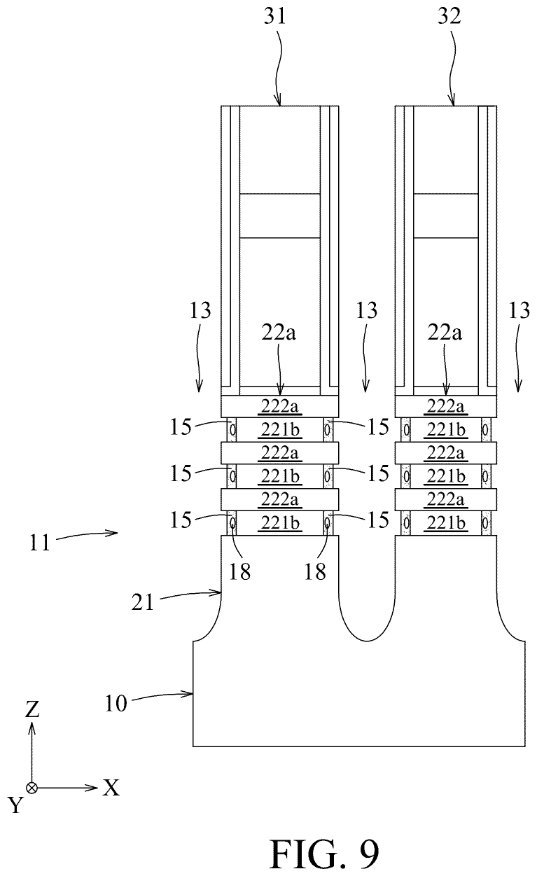

In some embodiments, in each of formulae (I-1) and (I-2), when r is zero (i.e., the second repeating units are absent), q is greater than p. In certain embodiments, a value of ratio of p to q (hereinafter referred to as p/q ratio) ranges from about 2/8 to about 4/6. When the p/q ratio is greater than about 4/6, an air gap structure 18 (see FIG. 9 to be described later) is less likely to be formed in subsequent process(es). On the contrary, when the p/q ratio is less than about 2/8, the silicon-containing polymer is less likely to be dissolved stably in the solvent, which may cause inconvenience in practical application of the silicon-containing polymer. In certain embodiments, p is an integer ranging from about 25 to about 35, q is an integer ranging from about 65 to about 75, and r is zero.

In some other embodiments, in each of formulae (I-1) and (I-2), when r is an integer greater than zero, q is greater than r. In certain embodiments, the q/r ratio ranges from about 1/1 to about 4/1, from about 1/1 to about 2/1, from about 1/1 to about 5/3, from about 1/1 to about 3/2, or from about 1/1 to about 4/3. In some embodiments, a value of ratio of p to a sum of q and r (hereinafter referred to p/(q+r) ratio) ranges from about 2/8 to about 8/2, from about 3/5 to about 7/5, or from about 4/5 to about 6/5. When the q/r ratio is too large (e.g., greater than about 4/1) and/or the p/(q+r) ratio is too large (e.g., greater than about 8/2), the air gap structure 18 (see FIG. 9 to be described later) is less likely to be formed in subsequent process(es). On the contrary, when the q/r ratio is too small (e.g., smaller than about 1/1) and/or the p/(q+r) ratio is too small (e.g., smaller than about 2/8), the silicon-containing polymer is less likely to be dissolved stably in the solvent, which may cause inconvenience in practical application of the silicon-containing polymer. In certain embodiments, p is an integer ranging from about 20 to about 80, q is an integer ranging from about 10 to about 40, and r is an integer ranging from about 10 to about 40.

In some embodiments, the silicon-containing polymer has a molecular weight ranging from about 1000 to about 20000, or about 3000 to about 20000. When the molecular weight of the silicon-containing polymer is too small (e.g., smaller than about 1000), the viscosity of the mixture 16 may not be high enough for practical use in spin-coating process. When the molecular weight of the silicon-containing polymer is too large (e.g., greater than about 20000), the mixture 16 may be less likely to fill the pairs of grooves 14 and the source/drain recesses 13.

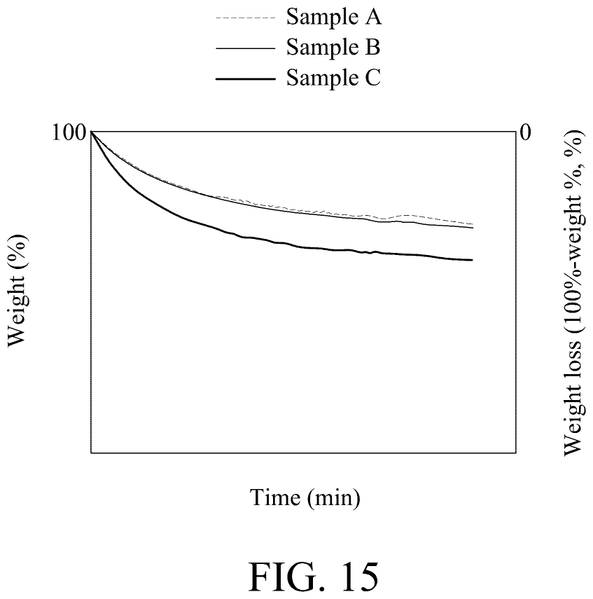

FIG. 15 is a graph illustrating thermogravimetric analysis (TGA) results of Samples A, B and C, in which Samples A, B and C are different silicon containing polymers in accordance with some embodiments. During the thermogravimetric analysis, Samples A, B and C are each heated to about 450° C. for a time period of about 90 minutes, and then the variation in the percentage of weight (left vertical axis) and the percentage of weight loss (right vertical axis) of the silicon-containing polymer over time is measured.

Each of Samples A, B and C is represented by formula (I-1) as described above. Furthermore, the relationship of the values of p, q, r, the p/q ratio, and the p/(q+r) ratio are listed in Table 1 below.

TABLE 1

| | p | q | r | p/q ratio | p/(q + r) ratio |
|---|---|---|---|---|---|
| Sample A | P1 | Q1 | 0 | M1 | N1 |
| Sample B | P2 | Q2 | 0 | M2 | N2 |
| Sample C | P3 | Q3 | >0 | M3 | N3 |

Note:
(i) P1 ≈ P3 > P2
(ii) Q2 > Q1 > Q3
(iii) M3 > M1 > M2
(iv) N1 ≈ N3 > N2

As shown in FIG. 15, the percentage of total weight loss of Sample B is slightly greater than the percentage of total weight loss of Sample A, and the percentage of total weight loss of Sample C is much greater than the percentage of total weight loss of each of Samples A and B. These results indicate that, with the provision of the second repeating units (each including the second functional unit, i.e., r>0) in the silicon-containing polymer, an air gap structure may be more likely to be formed in the silicon-containing polymer after, for example, but not limited to, a thermal treatment.

In some embodiments, the solvent includes n-butyl acetate, 2-heptanone, propylene glycol methyl ether (PGME), propylene glycol 1-ethyl ether (PGEE), cyclohexanone (CHN), gamma-butyrolactone (GBL), propylene glycol methyl ether acetate (PGMEA), methyl isobutyl carbinol (MIBC), or combinations thereof. Other solvents suitable for the silicon-containing polymer to be dissolved therein are also within the contemplated scope of the present disclosure. In some embodiments, the spin-on coating process is performed at a spin rate ranging from about 1000 rpm (revolutions per minutes) to about 2000 rpm, but is not limited thereto. It is noted that the spin rate may vary depending on, for example, the viscosity of the solvent used in the mixture 16 or the concentration of the silicon-containing polymer in the mixture 16.

Next, as shown in FIG. 7, a baking process is performed to remove the solvent from the mixture 16 (see FIG. 6), such that the mixture 16 is formed into a dielectric filler 17 which includes the silicon-containing polymer that is not removed by the baking process. The dielectric filler 17 is disposed over the dummy structures 31, 32 such that the dielectric filler 17 fills the pairs grooves 14 and the source/drain recesses 13. In some embodiments, the dielectric filler 17 may include silicon, oxygen, carbon, nitrogen, or other elements included or substituted in the first or second functional units. In some embodiments, the dielectric filler 17 may include silicon in an atomic concentration ranging from about 8% to about 14%, oxygen in an atomic concentration ranging from about 16% to about 28%, carbon in an atomic concentration ranging from about 27% to about 39%, and hydrogen in an atomic concentration ranging from about 31% to about 39%. In some embodiments, the dielectric filler 17 has a film density ranging from about 1.3 g/cm³ to about 1.5 g/cm³. In comparison with a film density (e.g., about 1.8 g/cm³ to about 2.3 g/cm³) of a dielectric film formed by CVD or ALD, the dielectric filler 17 has a relatively low film density.

In some embodiments, a hot plate may be used to heat the structure shown in FIG. 6 during the baking process. In some embodiments, the baking process is performed at a baking temperature that is at least greater than a boiling point of the solvent. In some embodiments, the baking temperature ranges from about 150° C. to 250° C. In some embodiments, the baking process is performed for a time period ranging from about 1 minute to about 5 minutes to completely remove the solvent. In some embodiments, the baking process is performed in the presence of air. In some embodiments, when the silicon-containing polymer includes nitrogen, the baking process is performed in the presence of nitrogen gas, so as to prevent the loss of nitrogen in the silicon-containing polymer.

After the baking process, an anisotropic etching process is performed on the dielectric filler 17 (see FIG. 7), while leaving portions of the dielectric filler 17 beneath the dummy structures 31, 32 intact, as shown in FIG. 8. In other words, the portions of the dielectric filler 17 respectively in the grooves 14 (see FIG. 5) remained without being removed, thereby serving as the inner spacers 15. In some embodiments, the anisotropic etching process includes a dry etching process, a plasma etching process, or other etching process without use of chemical gas.

In some embodiments, after the anisotropic etching process, a chemical gas may be applied to partially remove each of the inner spacers 15 so as to form the air gap structure 18, as shown in FIG. 9. In some embodiments, the chemical gas includes hydrogen fluoride gas (HF), ammonia gas (NH₃), or a combination thereof. In some embodiments, in the case that the value of r in formula (I-1) or (I-2) is an integer greater than zero, the chemical gas can be applied at a relatively low temperature (e.g., about room temperature to 35° C.) to permit the air gap structure 18 to be formed in each of the inner spacers 15. In some other embodiments, in the case that the value of r in formula (I-1) or (I-2) is zero, the chemical gas is applied at a relatively high temperature (e.g., about 80° C. to 120° C.) to permit the air gap structure 18 to be formed in each of the inner spacers 15.

In some alternative embodiments, the application of the chemical gas may be omitted. In such case, the air gap structure 18 will be formed in step S06.

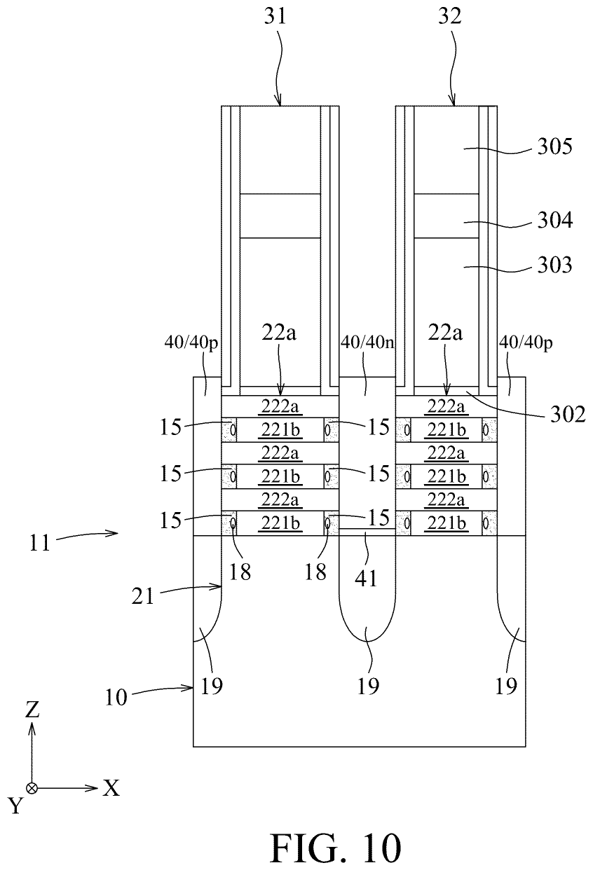

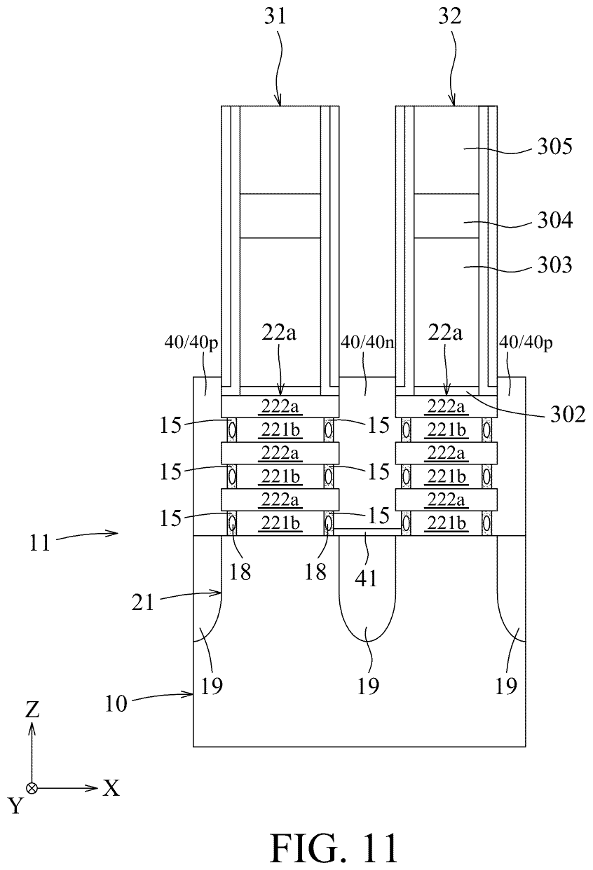

Referring to FIG. 1 and the examples illustrated in FIGS. 10 and 11, the method 1 proceeds to step S06, where source/drain portions 40 are formed to fill the source/drain recesses 13, respectively. FIGS. 10 and 11 are schematic sectional views respectively similar to those of FIGS. 8 and 9, but illustrating the structures after step S06.

In some embodiments, prior to formation of the source/drain portions 40, epitaxial portions 19 are formed. The epitaxial portions 19 are respectively formed in lower regions of the source/drain recesses 13. In some embodiments, a level of an upper surface of each of the epitaxial portions 19 may be slightly higher or lower than or equal to a bottom surface of a corresponding adjacent one of the stacking portions 22a due to variation of process parameter(s) (e.g., process time, temperatures, etc.) for forming the epitaxial portions 19.

In some embodiments, each of the epitaxial portions 19 includes a semiconductor material (such as the examples of the semiconductor material for forming the substrate 10). In some embodiments, each of the epitaxial portions 19 is made of silicon. In some embodiments, each of the epitaxial portions 19 is formed by a first epitaxial growth process (such as molecular-beam epitaxy (MBE), selective area epitaxy (SAE), etc.), or other suitable deposition techniques.

Each of the source/drain portions 40 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 40 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or boron compound (for example, B, ¹¹B, BF₂), aluminum (Al), gallium (Ga), indium (In), other suitable p-type dopants, or combinations thereof. In some embodiments, formation of the source/drain portions 40 may include forming epitaxial regions respectively formed on the epitaxial portions 19 by a second epitaxial growth process or other suitable deposition techniques, followed by an implantation process for introducing the n-type dopant or the p-type dopant into the epitaxial regions. As such, the second films 222a in each of the stacking portions 22a each extends between two corresponding adjacent ones of the source/drain portions 40. In some alternative embodiments, the implantation process may be omitted, and the n-type dopant or the p-type dopant may be in-situ doped in the epitaxial regions during the second epitaxial growth process. In some embodiments, the second epitaxial growth process includes MBE, an epitaxial deposition/partial etch process (such as a cyclic deposition-etch (CDE) process, and/or a selective epitaxial growth (SEG) process), but the disclosure is not limited to the above processes.

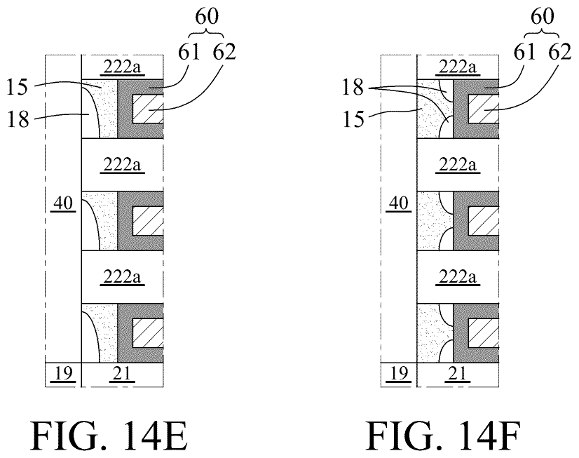

In some embodiments, the first and second epitaxial growth processes are performed at an epitaxial temperature ranging from about 800° C. to about 1000° C. In some embodiments, as shown in FIG. 10, due to the decomposition or dissociation of the second functional unit in the silicon-containing polymer at such elevated epitaxial temperature, the air gap structure 18 is simultaneously formed in each of the inner spacers 15 during the first and/or second epitaxial growth processes. In some alternative embodiments, the volume of the silicon-containing polymer shrinks during the first and/or second epitaxial growth processes, such that the air gap structure 18 is formed in each of the inner spacers 15. In some other embodiments, compared with the volume of the air gap structure 18 in each of the inner spacers 15 before the epitaxial growth processes (see FIG. 9), the volume of the air gap structure 18 increases after the first and/or second epitaxial growth processes. In some embodiments, the first functional unit in the silicon-containing polymer may be also decomposed or dissociated during the first and/or second epitaxial growth processes. In some embodiments, the decomposition or dissociation of the second functional unit occurs earlier than the decomposition or dissociation of the first functional unit. In some embodiments, after step S06, the amount of the first functional unit remaining in the silicon-containing polymer may be greater than the amount of the second functional unit remaining in the silicon-containing polymer. In some embodiments, in the case that the first and/or second functional unit in the silicon-containing polymer is not completely decomposed or dissociated after step S06, each pair of the inner spacers 15 thus obtained may be made of carbon-doped silicon oxide (SiOC), carbon-doped silicon oxynitride (SiOCN), or carbon-doped silicon nitride (SiCN). In some other embodiments, in the case that the first and second functional unit in the silicon-containing polymer are completely decomposed or dissociated after step S06, each pair of the inner spacers 15 thus obtained may be made of silicon oxide (SiO) or silicon nitride (SiN). It is noted that the degree of decomposition or dissociation of the first and second functional units, as well as the configuration or shape of the air gap structure 18, depend on the chemical properties of the first and second functional units selected in step S05. In addition, when subsequent processes are performed at a temperature not greater than the epitaxial temperature, the configuration or shape of the air gap structure 18 obtained in step S06 is less likely to change in the subsequent processes. Other examples for the configuration or shape of the air gap structure 18 are shown in FIGS. 14A to 14F, and will be described later.

In some embodiments, the source/drain portions 40 may include p-type source/drain portions 40p and an n-type source/drain portion 40n. The n-type source/drain portion 40n may be formed after or before formation of the p-type source/drain portions 40p. In some embodiments, a dielectric portion 41 is further formed between the n-type source/drain portion 40n and a corresponding lower one of the epitaxial portions 19 for electrical isolation. Possible materials suitable for the dielectric portion 41 are similar to those for the spacers 306, and thus the details thereof are omitted for the sake of brevity. The dielectric portion 41 may be formed by CVD, ALD, or other suitable deposition techniques.

Referring to FIG. 1 and the examples illustrated in FIGS. 12 and 13, the method 1 proceeds to step S07, where inter-layer dielectric (ILD) layers 42 are respectively formed over the source/drain portions 40 (40n, 40p), and then a replacement gate process is performed, thereby obtaining the semiconductor structure 2 including the two GAAFETs 3. FIGS. 12 and 13 are schematic sectional views respectively similar to those of FIGS. 10 and 11, but illustrating the structures after step S07.

In some embodiments, the ILD layers 42 may include silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof. In some embodiments, formation of the ILD layers 42 may include forming a material layer (not shown) for the ILD layers 42 on the source/drain portions 40 and the dummy structures 31, 32 (see FIGS. 10 and 11) using CVD, PVD, ALD or other possible processes, followed by a planarization process (e.g., CMP) to expose the dummy gate 303 of each of the dummy structures 31, 32 (see FIG. 10 or 11).

In the replacement gate process, the dummy gate 303 and the dummy dielectric 302 in each of the dummy structures 31, 32 (see FIG. 10 or 11) are removed to expose the stacking portions 22a of the fin structure 11. Then, the recessed first films 221b (see FIG. 10 or 11) of the stacking portions 22a of the fin structure 11 are selectively removed, while the second films 222a (i.e., the channel films) in the fin structure 11 are substantially intact. As such, the second films 222a of the stacking portions 22a of the fin structure 11 serve as multiple stacks of channel films (also denoted by 222a). Each channel film 222a in each stack has two opposite end portions in the Y direction and a peripheral surface extending between the two opposite end portions. Afterwards, the gate structures 60 are each formed to surround the peripheral surface of each channel film 222a in a respective one of the stacks. Each of the gate structures 60 is separated from two corresponding adjacent ones of the source/drain portions 40 by corresponding pairs of the inner spacers 15.

Each of the GAAFETs 3 includes one of the gate structures 60, the channel films 222a of the respective stack which is surrounded by the one of the gate structures 60, and two corresponding adjacent ones of the source/drain portions 40 which are respectively located at two opposite sides of the one of the gate structures 60.

In some embodiments, each of the gate structures 60 includes a gate dielectric 61 and a gate electrode 62. The gate electrode 62 is separated from the corresponding stack of the channel films 222a by the gate dielectric 61. The gate electrode 62 may include a work function metal. In some embodiments, the gate dielectric 601 includes a metal-containing high-k dielectric layer. The metal-containing high-k dielectric layer includes, for example, but not limited to, Hf-containing dielectric oxide materials, Ta-containing dielectric oxide materials (e.g., Ta₂O₅), Ti-containing dielectric oxide materials, Zr-containing dielectric oxide materials, Al-containing dielectric oxide materials (e.g., Al₂O₃), La-containing dielectric materials, other suitable materials (having a dielectric constant not less than about 9 or larger than about 13), or combinations thereof. The materials (e.g. an electrically conductive material and the work function metal material) of the gate electrode 62 may include, for example, but not limited to, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), or the like, or combinations thereof. Other suitable materials for forming the gate dielectric 61 and the gate electrode 62 are within the contemplated scope of the present disclosure.

In some embodiments not shown herein, an interconnect structure may be further formed on the semiconductor structure 2, so as to permit an operating voltage to be applied to each of the source/drain portions 40 and the gate electrode 62 of each of the gate structures 60. In some embodiments, the interconnect structure may include an inter-metal dielectric (IMD) portion in which a plurality of electrically conductive elements (for example, metal contacts, metal lines and/or metal vias) are formed so as to permit each of the source/drain portions 40 and the gate electrode 62 of each of the gate structures 60 to be electrically connected to a power supply through the electrically conductive elements. The interconnect structure may be formed by a dual damascene process, a single damascene process, or other suitable back-end-of-line (BEOL) techniques.

FIGS. 14A to 14F are enlarged fragmentary sectional views of area B shown in FIG. 12, but illustrating the configuration or shape of the air gap structure 18 in each in accordance with some different embodiments.

In some embodiments, as shown in FIG. 14A, the air gap structure 18 includes air gaps which are evenly distributed in each of the inner spacers 15. In some embodiments, as shown in FIGS. 14B and 14C, the air gap structure 18 is an air gap which is formed between one of the gate structures 60 and the respective inner spacer 15. In FIG. 14B, a volume of each of the air gap structures 18 is smaller than that of the respective inner spacer 15. In FIG. 14C, a volume of each of the air gap structures 18 is larger than that of the respective inner spacer 15. In some embodiments, as shown in FIGS. 14D and 14E, each of the air gap structures 18 is an air gap which is formed between one of the source/drain portions 40 and the respective inner spacer 15. In FIG. 14D, each of the inner spacer 15 is not in contact with the corresponding source/drain portion 40. In FIG. 14E, each of the inner spacer 15 is in contact with the corresponding source/drain portion 40. In some embodiments, as shown in FIG. 14F, each of the air gap structures 18 includes air gaps which are in contact with an adjacent one of the gate structures 60, and the each of the inner spacer 15 is in contact with the adjacent one of the gate structures 60.

In some embodiments, some steps in the method 1 may be modified, replaced, or eliminated without departure from the spirit and scope of the present disclosure. In some alternative embodiments, the semiconductor structure 2 may further include additional features, and/or some features present in the semiconductor structure 2 may be modified, replaced, or eliminated without departure from the spirit and scope of the present disclosure. For example, the mixture 16 may be applied to fill a vertical groove by a spin-on coating process. Afterwards, the baking process is performed to remove the solvent from the mixture 16 such that the mixture 16 is formed into the dielectric filler 17. Subsequently, the air gap structure 18 may be formed in the dielectric filler 17 by applying the chemical gas to the dielectric filler 17 or by performing a thermal treatment on the dielectric filler 17 at an elevated temperature ranging from about 800° C. to about 1000° C.

In summary, the inner spacers 15 can be formed by a spin-on coating process, followed by a baking process and an anisotropic etching process. Since the silicon-containing polymer used in the spin-on coating process is designed to include the first repeating units (each including the first functional unit) and the second repeating units (each including the second functional unit), the air gap structure 18 can be formed in each of the inner spacers 15, thereby reducing the dielectric constant of each of the inner spacers 15. The performance (e.g., computing speed, power consumption, heat generation, etc.) of an integrated circuit formed from the semiconductor structure is improved accordingly. Furthermore, in comparison with the temperature used in CVD or ALD, the spin-on coating process and the baking process are both performed at a relatively low temperature. That is, the inner spacers 15 are formed with a relatively low thermal budget. Therefore, undesired diffusion of elements (e.g., germanium, boron, fluorine) in the semiconductor structure may be alleviated or eliminated.

In accordance with some embodiments of the present disclosure, a method for forming an air gap structure in a semiconductor structure includes: forming a stacking portion on a substrate, the stacking portion including a first semiconductor layer and a second semiconductor layer disposed on the first semiconductor layer; recessing the first semiconductor layer to form two grooves which are respectively located beneath two end portions of the second semiconductor layer; forming two inner spacers to fill the two grooves, respectively; and performing a treatment such that the air gap structure is formed in each of the two inner spacers.

In accordance with some embodiments of the present disclosure, before the treatment, each of the two inner spacers includes a silicon-containing polymer which is represented by formula (I):

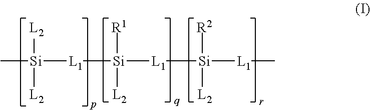

wherein
L₁ is oxygen or nitrogen,
L₂ is a hydroxyl group (OH) when L₁ is oxygen,
L₂ is hydrogen when L₁ is nitrogen,
R¹ is a substituted or non-substituted C4 to C10 aromatic group, or a substituted or non-substituted C3 to C10 cycloalkyl group,
R² is a substituted or non-substituted C1 to C5 alkyl group,
each of p and q is an integer greater than zero, and
r is an integer not less than zero.

In accordance with some embodiments of the present disclosure, r is an integer greater than zero.

In accordance with some embodiments of the present disclosure, q is not less than r.

In accordance with some embodiments of the present disclosure, a value of ratio of q to r ranges from 1/1 to 4/1.

In accordance with some embodiments of the present disclosure, the silicon-containing polymer has a molecular weight ranging from 1000 to 20000.

In accordance with some embodiments of the present disclosure, in the treatment, a chemical gas is applied to partially remove each of the two inner spacers so as to form the air gap structure.

In accordance with some embodiments of the present disclosure, the chemical gas includes hydrogen fluoride gas (HF), ammonia gas (NH₃), or a combination thereof.

In accordance with some embodiments of the present disclosure, in the treatment, each of the two inner spacers is partially decomposed to form the air gap structure.

In accordance with some embodiments of the present disclosure, the treatment is performed at a temperature ranging from 800° C. to 1000° C.

In accordance with some embodiments of the present disclosure, a method for forming an air gap structure includes: forming a groove in a patterned structure; applying a mixture such that the mixture fills the groove, the mixture including a solvent and a silicon-containing polymer dissolved in the solvent, the silicon-containing polymer having a backbone which includes silicon; removing the solvent from the mixture to form a dielectric filler which fills the groove; and performing a treatment on the dielectric filler such that the air gap structure is formed in the dielectric filler.

In accordance with some embodiments of the present disclosure, the silicon-containing polymer is represented by formula (I):

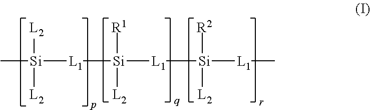

wherein
L₁ is oxygen or nitrogen,
L₂ is a hydroxyl group (OH) when L₁ is oxygen,
L₂ is hydrogen when L₁ is nitrogen,
R¹ is a substituted or non-substituted C4 to C10 aromatic group, or a substituted or non-substituted C3 to C10 cycloalkyl group,
R² is a substituted or non-substituted C1 to C5 alkyl group,
each of p and q is an integer greater than zero, and
r is an integer not less than zero.

In accordance with some embodiments of the present disclosure, the solvent includes n-butyl acetate, 2-heptanone, propylene glycol methyl ether (PGME), propylene glycol 1-ethyl ether (PGEE), cyclohexanone (CHN), gamma-butyrolactone (GBL), propylene glycol methyl ether acetate (PGMEA), methyl isobutyl carbinol (MIBC), or combinations thereof.

In accordance with some embodiments of the present disclosure, the mixture is applied by a spin-on coating process such that the mixture fills the groove.

In accordance with some embodiments of the present disclosure, the solvent is removed from the mixture by a baking process which is conducted at a temperature that is greater than a boiling point of the solvent.

In accordance with some embodiments of the present disclosure, the method further includes, before applying the mixture, cleaning an inner surface of the groove.

In accordance with some embodiments of the present disclosure, a semiconductor structure includes: a channel on a substrate, the channel having a two end portions and a peripheral surface extending between the two end portions; a gate structure surrounding the peripheral surface of the channel; two source/drain portions which are respectively connected to the two end portions of the channel, two inner spacers disposed respectively beneath the two end portions of the channel so as to separate the gate structure from the two source/drain portions; and two air gap structures respectively formed in the two inner spacers.

In accordance with some embodiments of the present disclosure, each of the two air gap structures includes air gaps which are evenly distributed in a respective one of the two inner spacers.

In accordance with some embodiments of the present disclosure, each of the two air gap structures is an air gap which is formed between the gate structure and a respective one of the two inner spacers.

In accordance with some embodiments of the present disclosure, each of the two air gap structures is an air gap which is formed between one of the two source/drain portions and a respective one of the two inner spacers.

In accordance with some embodiments of the present disclosure, a method for forming an air gap structure in a semiconductor structure, comprising: forming a stacking portion on a substrate, the stacking portion including a first semiconductor layer and a second semiconductor layer disposed on the first semiconductor layer; recessing the first semiconductor layer to form two grooves which are respectively located beneath two end portions of the second semiconductor layer; forming a spacer layer which covers the stacking portion and which fills the two grooves; patterning the spacer layer until the two opposite end portions of the second semiconductor layer are exposed, such that the spacer layer is formed into two inner spacers respectively filling the two grooves; and performing a treatment such that the air gap structure is formed in each of the two inner spacers.

In accordance with some embodiments of the present disclosure, before the treatment, the spacer layer includes a silicon-containing polymer which is represented by formula (I):

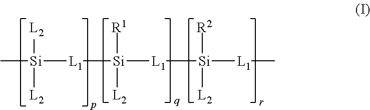

wherein
L₁ is oxygen or nitrogen,
L₂ is a hydroxyl group (OH) when L₁ is oxygen,
L₂ is hydrogen when L₁ is nitrogen,
R¹ is a substituted or non-substituted C4 to C10 aromatic group, or a substituted or non-substituted C3 to C10 cycloalkyl group,
R² is a substituted or non-substituted C1 to C5 alkyl group,
each of p and q is an integer greater than zero, and
r is an integer not less than zero.

In accordance with some embodiments of the present disclosure, r is an integer greater than zero, and q is not less than r.

In accordance with some embodiments of the present disclosure, r is zero, and q is greater than p.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming an air gap structure in a semiconductor structure, comprising:
forming a stacking portion on a substrate, the stacking portion including a first semiconductor layer and a second semiconductor layer disposed on the first semiconductor layer;
recessing the first semiconductor layer to form two grooves which are respectively located beneath two end portions of the second semiconductor layer;
forming two inner spacers to fill the two grooves, respectively; and
performing a treatment such that the air gap structure is formed in each of the two inner spacers.

2. The method as claimed in claim 1, wherein before the treatment, each of the two inner spacers includes a silicon-containing polymer which is represented by formula (I): 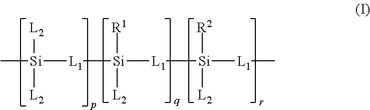
wherein
L₁ is oxygen or nitrogen,
L₂ is a hydroxyl group (OH) when L₁ is oxygen,
L₂ is hydrogen when L₁ is nitrogen,
R¹ is a substituted or non-substituted C4 to C10 aromatic group, or a substituted or non-substituted C3 to C10 cycloalkyl group,
R² is a substituted or non-substituted C1 to C5 alkyl group,
each of p and q is an integer greater than zero, and
r is an integer not less than zero.

3. The method as claimed in claim 2, wherein r is an integer greater than zero.

4. The method as claimed in claim 3, wherein q is not less than r.

5. The method as claimed in claim 4, wherein a value of ratio of q to r ranges from 1/1 to 4/1.

6. The method as claimed in claim 2, wherein the silicon-containing polymer has a molecular weight ranging from 1000 to 20000.

7. The method as claimed in claim 1, wherein, in the treatment, a chemical gas is applied to partially remove each of the two inner spacers so as to form the air gap structure.

8. The method as claimed in claim 7, wherein the chemical gas includes hydrogen fluoride gas (HF), ammonia gas (NH₃), or a combination thereof.

9. The method as claimed in claim 1, wherein, in the treatment, each of the two inner spacers is partially decomposed to form the air gap structure.

10. The method as claimed in claim 9, wherein the treatment is performed at a temperature ranging from 800° C. to 1000° C.

11. A method for forming an air gap structure, comprising:
forming a groove in a patterned structure;
applying a mixture such that the mixture fills the groove, the mixture including a solvent and a silicon-containing polymer dissolved in the solvent, the silicon-containing polymer having a backbone which includes silicon;
removing the solvent from the mixture to form a dielectric filler which fills the groove; and
performing a treatment on the dielectric filler such that the air gap structure is formed in the dielectric filler.

12. The method as claimed in claim 11, wherein the silicon-containing polymer is represented by formula (I): 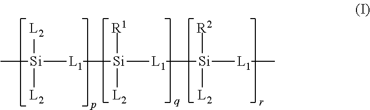
wherein
L₁ is oxygen or nitrogen,
L₂ is a hydroxyl group (OH) when L₁ is oxygen,
L₂ is hydrogen when L₁ is nitrogen,
R¹ is a substituted or non-substituted C4 to C10 aromatic group, or a substituted or non-substituted C3 to C10 cycloalkyl group,
R² is a substituted or non-substituted C1 to C5 alkyl group,
each of p and q is an integer greater than zero, and
r is an integer not less than zero.

13. The method as claimed in claim 11, wherein the solvent includes n-butyl acetate, 2-heptanone, propylene glycol methyl ether (PGME), propylene glycol 1-ethyl ether (PGEE), cyclohexanone (CHN), gamma-butyrolactone (GBL), propylene glycol methyl ether acetate (PGMEA), methyl isobutyl carbinol (MIBC), or combinations thereof.

14. The method as claimed in claim 11, wherein the mixture is applied by a spin-on coating process such that the mixture fills the groove.

15. The method as claimed in claim 11, wherein the solvent is removed from the mixture by a baking process which is conducted at a temperature that is greater than a boiling point of the solvent.

16. The method as claimed in claim 11, further comprising, before applying the mixture, cleaning an inner surface of the groove.

17. A semiconductor structure, comprising:
a channel on a substrate, the channel having a two end portions and a peripheral surface extending between the two end portions;
a gate structure surrounding the peripheral surface of the channel;
two source/drain portions which are respectively connected to the two end portions of the channel,
two inner spacers disposed respectively beneath the two end portions of the channel so as to separate the gate structure from the two source/drain portions; and
two air gap structures respectively formed in the two inner spacers.

18. The semiconductor structure as claimed in claim 17, wherein each of the two air gap structures includes air gaps which are evenly distributed in a respective one of the two inner spacers.

19. The semiconductor structure as claimed in claim 17, wherein each of the two air gap structures is an air gap which is formed between the gate structure and a respective one of the two inner spacers.

20. The semiconductor structure as claimed in claim 17, wherein each of the two air gap structures is an air gap which is formed between one of the two source/drain portions and a respective one of the two inner spacers.
